(19) United States
(12) Patent Application Publication
(10) Pub. No.: US 2012/0187952 A1
(43) Pub. Date: Jul. 26, 2012

(54) Capacitive Page Opening Detector

(76) Inventor: David M. Coombs, Tucson, AZ (US)

(21) Appl. No.: 13/011,866

(22) Filed: Jan. 22, 2011

(51) Int. Cl. G01R 31/08

(52) U.S. Cl. 324/519

(57) ABSTRACT

An array of capacitor plates is disclosed wherein each plate is the foundation on which a page of printed material is built. Capacitance is sequentially detected between nearby pages to determine where capacitive interaction fails, thus determining the page opening. Any number of pages can be scanned in this manner without the use of buttons, switches or pointing devices. Page openings can be determined to provide automatic audible narration that is pertinent to the contents of each page, even when randomly opened.

### RELATED APPLICATIONS

The present application is related to United States patent number 2008/0268415, issued Oct. 30, 2008, for AUDIO BOOK, included by reference herein.

The present application is related to United States patent number 2006/0071912, issued Apr. 6, 2006, for VIBRATION SENSING TOUCH INPUT DEVICE, included by reference herein.

The present application is related to United States patent number 2004/0043371, issued Mar. 4, 2004, for INTERACTIVE MULTI-SENSORY READING SYSTEM ELECTRONIC TEACHING/LEARNING AID, included by reference herein.

The present application is related to United States patent number 2004/0043365, issued Mar. 4, 2004, for ELECTRONIC LEARNING DEVICE FOR AN INTERACTIVE MULTI-SENSORY READING SYSTEM, included by reference herein.

The present application is related to U.S. Pat. No. 7,621,441, issued Nov. 24, 2009, for INTERACTIVE DEVICE USING CAPACITIVE SENSOR ARRAY FOR JOINT PAGE IDENTIFICATION AND PAGE LOCATION DETERMINATION, included by reference herein.

The present application is related to U.S. Pat. No. 7,203,455, issued Apr. 10, 2007, for INTERACTIVE MULTI-SENSORY READING SYSTEM ELECTRONIC TEACHING/LEARNING AID, included by reference herein.

The present application is related to U.S. Pat. No. 7,111,774, issued Sep. 26, 2006, for METHOD AND SYSTEM FOR ILLUSTRATING SOUND AND TEXT, included by reference herein.

The present application is related to U.S. Pat. No. 6,729,543, issued May 4, 2004, for PAGE IDENTIFICATION SYSTEM AND METHOD, included by reference herein.

The present application is related to U.S. Pat. No. 6,167,233, issued Dec. 26, 2000, for DEVICE FOR RECORDING MULTIPLE DISCRETE MESSAGES FOR A BOOK, included by reference herein.

The present application is related to U.S. Pat. No. 6,064,855, issued May 16, 2000, for VOICE BOOK SYSTEM, included by reference herein.

The present application is related to U.S. Pat. No. 5,810,604, issued Sep. 22, 1998, for ELECTRONIC BOOK AND METHOD, included by reference herein.

The present application is related to U.S. Pat. No. 5,631,883, issued May 20, 1997, for COMBINATION OF BOOK WITH AUDIO DEVICE, included by reference herein.

The present application is related to U.S. Pat. No. 4,990,092, issued Feb. 5, 1991, for TALKING BOOK, included by reference herein.

The present application is related to U.S. Pat. No. 4,636,881, issued Jan. 13, 1987, for TALKING BOOK WITH AN INFRARED DETECTOR TO DETECT PAGE TURNING, included by reference herein.

The present application is related to U.S. Pat. No. 5,531,600, issued Jul. 2, 1996, for INTERACTIVE AUDIO VISUAL WORK, included by reference herein.

The present application is related to U.S. Pat. No. 5,511,980, issued Apr. 30, 1996, for TALKING PHONICS INTERACTIVE LEARNING DEVICE, included by reference herein.

The present application is related to U.S. Pat. No. 5,437,552, issued Aug. 1, 1995, for INTERACTIVE AUDIO VISUAL WORK, included by reference herein.

The present application is related to U.S. Pat. No. 5,356,296, issued Oct. 18, 1994, for AUDIO STORYBOOK, included by reference herein.

The present application is related to U.S. Pat. No. 5,569,868, issued Oct. 29, 1996, for SOUND GENERATING BOOK, included by reference herein.

### FIELD OF THE INVENTION

The present invention relates to printed audio books, and more particularly, to detecting when pages turn and to which page a book is opened.

### BACKGROUND OF THE INVENTION

Books that provide audio narrative that is relevant to a current page opening have been around for some time. Audio books thus far have had noticeably large compartments for batteries, electronics, and sensors. Most use trays or holders for inserting printed media. Many use buttons and switches or pointing devices to interact with the user. No other audio books have had all the page sensing technology, electronics, and batteries thin and compact enough to be cleanly integrated into a standard size hardback book with seemingly normal paper, normal book materials, and no noticeable gadgetry. Most importantly, no other audio book has been able to achieve such normal appearance in a cost effective manner.

Many kinds of books would benefit from page sensing and audio expression. Memory books will have written and audible questions and answers. Scrapbooks will have audible personality. History books will provide audio clips of historic events. Educational books will correlate pictures with sounds. School yearbooks will provide audio signatures from friends. What presents as text and pictures in the present art now presents as text, pictures, and audio. Audio offers a new characteristic to printed books that makes them communicate in a clearer, more concise, and personal manner.

There have been many creative designs over the years to detect page openings and some have seen great commercial success, especially in interactive children's books where large formats, thick and stiff pages, or pointing devices are acceptable.

U.S. Pat No. 7,621,441 reveals page sensing using capacitive means by electrically stimulating conductive pads, or tray sensors, in known locations found in a recessed tray that a special book or media sets into. The media uses spiral, comb, or other binding means that always allows the media pages to lay flat and substantially parallel to the tray. The media provides conductive markers built into strategic locations over selected tray sensors. The markers cause the tray sensor capacitance to change, which makes the presence or absence of markers detectable. Different patterns of conductive markers occur as pages turn, thus allowing determination of page openings.

U.S. Pat No. 5,569,868 discloses the use of individual transmitter and separate receiver sensors attached to two or more pages in a book. Page opening is determined by means of capacitive interaction between the dedicated transmitter and receiver sensors. Such sensors complicate the binding and add cost. It imposes severe limitations on the number of pages to which the sensors can be affixed because the sensors are placed in staggered positions along the book spine. The distance between pages is limited because of the small sensor area.

Several solutions utilize membrane switches of various forms in the book covers or pages that require a user to firmly press specific locations on pages to close switch contacts that are sent to an electronics module. Other solutions require the use of a keypad to enter codes that correspond to the pages being viewed where the keypad is off to one side and not part of the book pages. Several solutions require the use of a stylus or pointing device that may be attached to the book with an electric cable.

Methods created to discover book page openings are many, and solutions vary in their means and ability. Solutions that do not use a pointing stylus typically use large physical holders into which books or special media are placed. Most other solutions force severe page count limits. Many other solutions use active electronic sensors that create significant practical limitations on the number of hours of use between battery charges or battery replacement. Other solutions require the user to interact with switches or buttons that distract from the flow of the book as pages turn. A need exists for a cost effective page sensing technology that can automatically detect the page to which a book is opened, and that can be manufactured in a manner that mimics the characteristics of a typical book.

### SUMMARY OF THE INVENTION

An array of capacitor plates is disclosed wherein each individual capacitor plate is the primary foundation for a page of printed material. Capacitance is detected between nearby pages to determine where capacitive interaction fails, thus determining the page opening. Any number of pages can be scanned for capacitive interaction. A page opening is determined by failure of pages to capacitively interact, allowing the book to provide automatic audible narration that is pertinent to the contents of opened pages, even when randomly opened. The invention allows all of the page sensors and electronics to be fully integrated and hidden from view with no need for external connectors, buttons, switches or pointing devices.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a view of typical conductor patterns;

FIG. 2 is an illustration of a tap sensor inlaid into a main conductive plate;

FIG. 3 is a printable page with column connection array; and

FIG. 4 is an illustration of capacitive interactions as pages open and close.

For purposes of clarity and brevity, like elements and components will bear the same designations and numbering throughout the Figures.

### DESCRIPTION OF THE PREFERRED EMBODIMENT

It will be understood, both in the context of the prior art referred to above, and in the context of conductive and insulating materials in accordance with the invention, that capacitor plates are formed using an electrically-conductive material with an electrically-insulating material placed between them. Two capacitor plates, each having a face stacked on top of each other, create capacitance as a function of the common physical area of the two conductor plates' faces and the dielectric properties and thickness of the electrically insulating material between them. The capacitance between the plates reduces as the distance between the plates increase. Capacitance is not measurable if the plates move significantly apart, or the geometry changes so the plates are not stacked and substantially parallel.

The means of capacitive page opening detection claimed herein relies on capacitive exchanges between capacitor plates that form the pages in printed material. One example of a suitable conductor and insulator pair is metallized paper. Metallized paper has been available for some time and sold for use with home and office printers to provide a shimmering, metallic background for printed text and images. Similar shimmering, metallic looking paper is used for gift wrapping, greeting cards, product labels, food packaging, magazine covers, and many other consumer products. While the method of production of the metallized paper is immaterial to this invention, this paper typically has an ultra-thin layer of metal created by vacuum metallization over an electrically-insulating material such as paper. The bare metal finish of vacuum metallized paper is conductive and is a suitable material to create a plate of an electrical capacitor. A coating over the metallized layer is typically applied to protect the metal, and for use in this invention the coating of the capacitor plates may be translucent to allow the metallic shimmer to remain, may be of such a color to facilitate the paper's use as a printable surface that looks like standard paper, or may be any other similar electrically-insulating material that the end-user chooses.

If each page of a closed printed book is a conductive surface surrounded on one or both sides by a thin layer of insulation, the conductive surface will provide adequately large area, and the distance between pages will be adequately small to create detectable capacitance between adjacent pages. The plate area of a small book creates significant capacitance even when the pages lay against one another with small gaps between them. Such may be the case between the covers of the book and the pages that lay near them when the book is open.

Opening the book to an individual page destroys the capacitance between the two left and right facing pages because those plates are no longer close together or stacked. Under these conditions, capacitive interaction is not detectable between the two open pages. The capacitance between all other pages remains intact and detectable because those pages are still in close physical proximity, stacked, and substantially parallel. This will be true as long as the main conductive plate 1 does not protrude significantly into the page binding area because if the conductive plate 1 were to do so, stacked plates would be prevented from separating completely if the book binding is held firm. This condition would result in a constant detection of capacitive interaction even between the facing pages where the book is open. This condition is overcome by incorporating a binding isolation zone 14 that electrically disconnects the conductive plate 1 from the binding area. Multiple pages may be bound such that only the binding isolation zone on each page is immovably stacked, leaving the conductive plates free to be separated by the book's user.

While only one electrically-insulating material is necessary to form a capacitor using two capacitor plates, each capacitor plate in the preferred embodiment is coated with the electrically-insulating material on at least one of its faces. The electrically-insulating material may be formed from any material having substantial electrically-insulating properties.

The main conductive plate 1 of each page is electrically connected so that the capacitive interaction of each page can be detected. The binding is a convenient place to make that connection. The electrical connection is achieved by creating a conductor access point 16 as an extension of the main conductive plate 1 into the binding area as a narrow strip, running significantly deep into the binding area perpendicular to the book spine and at a unique and non-overlapping position relative to the connection access points from other pages. The inter-page capacitance created in the binding area from the connections will be insignificant and undetectable because the connections are created using relatively minuscule conductive areas that are staggered instead of stacked, thus creating a space where no stacked conductive areas exist that are electrically connected.

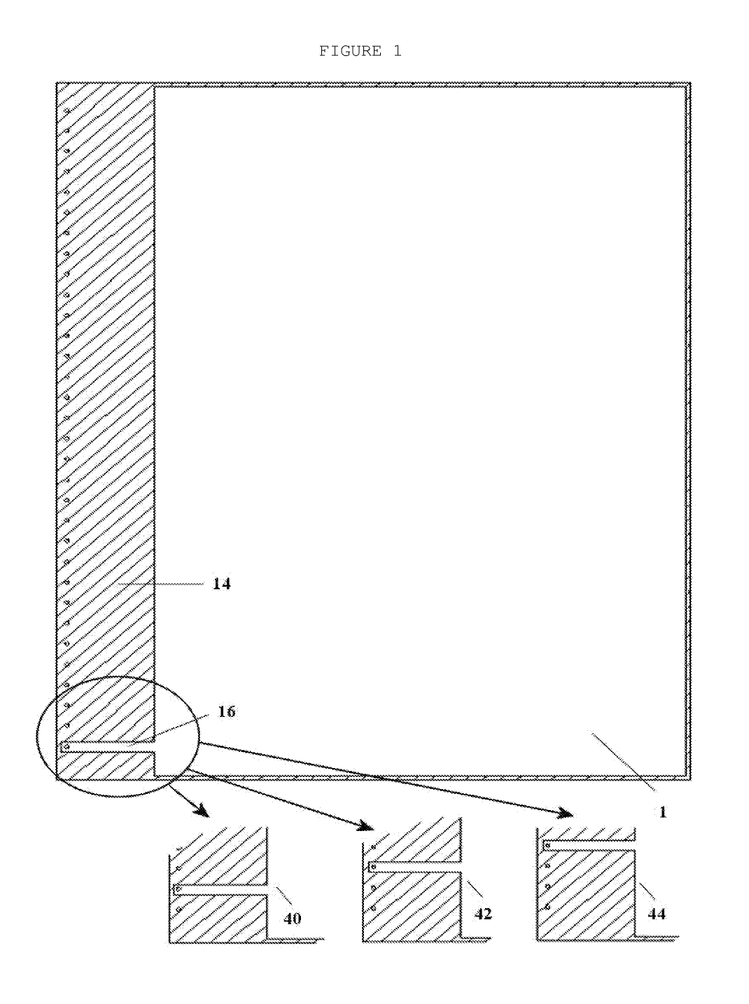

FIG. 1 shows a typical page with the insulation removed for clarity showing the main conductive plate 1, the binding isolation zone 14, and the conductor access point 16 that connects to the main conductive plate 1. The page shown in FIG. 1 shows a typical main conductor plate and conductor access point 16 pattern for pages one and two on the front and back sides of the main conductor plate. A typical staggered conductor access point 16 location for page three and four 40, page five and six 42, and page seven and eight 44 is also shown. The shape and location of each conductor access point 16 shown in FIG. 1 is not important as long as there is insignificant capacitance between two or more connection access points when the pages are stacked and bound.

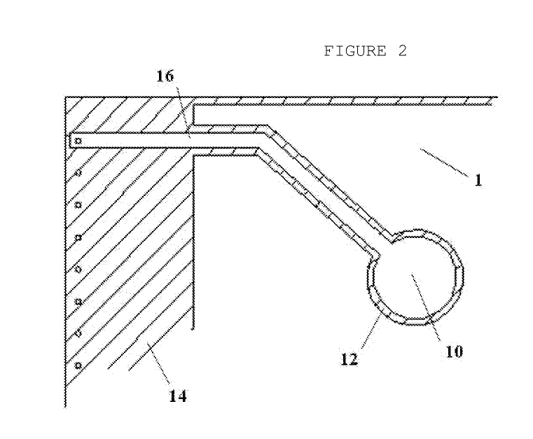

The preferred embodiment may also include a tap sensor plate 10, which is an area within the main conductive plate 1 electrically isolated from the main conductive plate 1 and used to identify a finger tap. FIG. 2 shows a typical isolation area 12 for a tap sensor and shows how the tap sensor physically routes and electrically connects to a conductor access point 16. The tap sensor has a natural capacitance relative to the conductive material that surrounds it. A finger touching the page over a tap sensor will change the tap sensor capacitance. A finger tap can be detected by reading a sudden change in the tap sensor capacitance.

Each conductor access point 16 must provide a unique electrical connection to the electronics module. This unique electrical connection can be established by any electrical means, including the use of wire, extension of the main conductive plate 1 material, or printed conductive material. The column array 22 is an optional series of electrical connection points running parallel and close to the binding area. Each connection point, or column pad 24, is electrically isolated from nearby column pads. Each column pad 24 electrically connects the top to bottom side of each page, and optionally connects to a conductor access point 16. Top to bottom continuity can be created using conductive ink that fills a via hole, electrically conductive material that folds or prints around the binding edge of the page, or any other conductive means. Stacked pages provide electrical continuity from the top to bottom side of the page stack through the column array 22 pads of individual pages. This forms several columns used for individual electrical connections to conductor access points of each individual page.

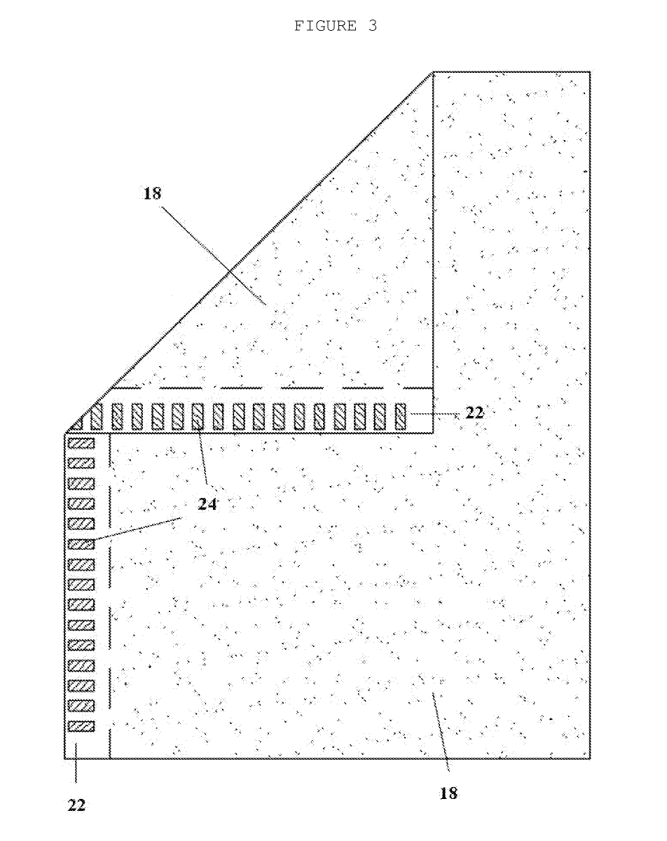

FIG. 3 shows a typical finished page with a column array 22 and column pads, and with the top corner folded over to show both sides. The insulator 18 is applied over the conductive material and isolation areas. Insulation can be any electrically insulating material such as paper lamination or a chemical coating. The result is a printable page made to perform as a single capacitor plate with electrical access provided at a single point.

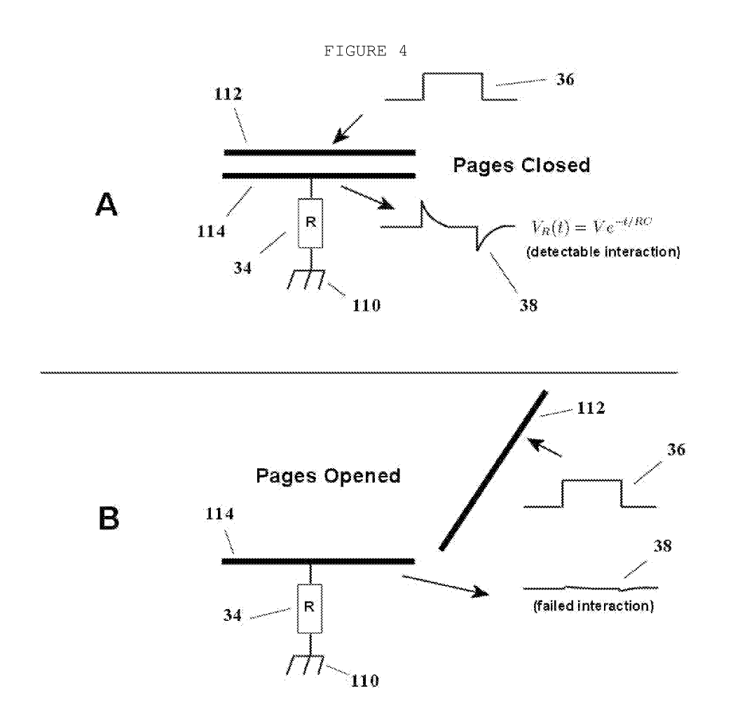

An electrical stimulus 36 is provided on a “driven” page and an interactive response 38 is detected on a nearby or “monitored” page. All active driving forces from the electronics module may be turned off on all monitored pages leaving those connections in a high impedance state. FIG. 4 shows the stimulus and response performed on two nearby pages with the pages closed against each other, and when the pages open. Passive voltage-bleeding resistors connect from a common DC voltage reference 110 to the main conductive plate 1 of each page to remove any residual electrical charge between nearby pages, and to hold the plate voltage to a known voltage reference 110 level. The impedance of the voltage-bleeding resistor 34 is overcome when driven by the electronics module.

FIG. 4-A shows the electrical interaction between the main conductive plate 1 of a driven page 112 and the monitored page 114 when the pages close against each other. When the electrical stimulus 36 is applied to a driven page 112, capacitive interaction can be detected from the monitored page 114.

FIG. 4-B shows the lack of electrical interaction between the driven page 112 and the monitored page 114 when pages are open. This condition destroys the capacitance between the main conductor plates of the driven and monitored pages, thus causing a significantly open circuit.

Detecting the presence of capacitance in a monitored page 114 may be performed using an electronic module to monitor voltage across a bleeding resistor 34 electrically attached to the monitored main conductive plate 1. The electronics module drives an initial page while monitoring the voltage across the bleeding resistor 34 connected to another page. The corresponding monitored page 114 produces a binary true or false response as a function of whether the voltage across the monitored bleeding resistor 34 has exceeded a predetermined voltage threshold. If the monitored voltage has exceeded the threshold then the pages being driven and monitored are in a closed position. If the monitored voltage has not exceeded the threshold then the driven and monitored pages are open. By sequencing through and testing each page, the electronics module can determine specific page openings by looking for one or more points where a monitored page 114 did not respond to electrical stimulus 36 from a driven page 112.

In the case of very low page counts, such as a greeting card or children's storybook, it may not be necessary to drive each page with stimulus because the page stack is thin enough such that all pages can capacitively interact to a single driven page. The specific page opening can be determined by detecting the first page where the capacitive interaction stops without going any further to scan the rest of the pages for interaction to the driven page. The same is true for groups of low page counts where each group only responds to a single driven page.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. Capacitive page opening detector, comprising:
A first conductive plate having a face with a face area and an orientation;
a second conductive plate having a face with a face area and a moveable orientation relative to the first conductive plate, where the orientation of the second conductive plate is capable of being placed adjacent to the face of said first conductive plate such that a portion of the face area of said second conductive plate overlaps a portion of the face area of said first conductive plate;
a dielectric member fixably attached to either said first conductive plate or to said second conductive plate such that the dielectric member electrically isolates the conductive plates;
a means for driving electrical stimulus to said first conductive plate electrically connected to said first conductive plate;
a means for measuring voltage changes between a known voltage level and said second conductive plate electrically connected to said second conductive plate;
a means for measuring the presence of capacitive interaction between said conductive plates electrically connected to said means for measuring voltage changes; and
a means for detecting whether capacitive interactions between said conductive plates is destroyed electrically connected to said means for measuring voltage changes.

2. The capacitive page opening detector in claim 1 further comprising:
one or more additional conductive plates, each of said additional conductive plates having: two faces with each face having a face area, and a moveable orientation relative to said first conductive plate, said second conductive plate, and to every other additional conductive plate, where the orientation of each additional conductive plate is capable of being placed adjacent to the face of said first conductive plate, said second conductive plate, or to the face of any other additional conductive plate such that a portion of the face area of the additional conductive plate overlaps a portion of the face area of the adjacent conductive plate;
a plurality of dielectric members fixably attached to said first conductive plate, to said second conductive plate, or to said additional conductive plates such that the dielectric members electrically isolate adjacent conductive plates;
a means for driving electrical stimulus to each additional conductive plate electrically connected to each said additional conductive plate;
a means for measuring voltage changes between a known voltage level and said additional conductive plate electrically connected to said additional conductive plate;
a means for measuring the presence of capacitive interaction between said additional conductive plate electrically connected to said means for measuring voltage changes; and
a means for detecting whether capacitive interactions between said additional conductive plate is destroyed electrically connected to said means for measuring voltage changes.

3. The capacitive page opening detector in claim 1 further comprising:
one or more additional conductive plates, each of said additional conductive plates having: two faces with each face having a face area, and a moveable orientation relative to said first conductive plate, said second conductive plate, and to every other additional conductive plate, where the orientation of each additional conductive plate is capable of being placed adjacent to the face of said first conductive plate, said second conductive plate, or to the face of any other additional conductive plate such that a portion of the face area of the additional conductive plate overlaps a portion of the face area of the adjacent conductive plate;
a plurality of dielectric members fixably attached to said first conductive plate, to said second conductive plate, or to said additional conductive plates such that the dielectric members electrically isolate adjacent conductive plates;
a means for measuring voltage changes between a known voltage and said additional conductive plate electrically connected to said conductive plate;
a means for measuring the presence of capacitive interaction between said additional conductive plate electrically connected to said means for measuring voltage changes; and
a means for detecting whether capacitive interactions between said conductive plates is destroyed electrically connected to said means for measuring voltage changes.

4. The capacitive page opening detector in claim 1 further comprising:
one or more additional conductive plates, each of said additional conductive plates having: two faces with each face having a face area; and a moveable orientation relative to said first conductive plate, said second conductive plate, and to every other additional conductive plate, where the orientation of each additional conductive plate is capable of being placed adjacent to the face of said first conductive plate, said second conductive plate, or to the face of any other additional conductive plate such that a portion of the face area of the additional conductive plate overlaps a portion of the face area of the adjacent conductive plate;
a plurality of dielectric members fixably attached to said first conductive plate, to said second conductive plate, or to said additional conductive plates such that the dielectric members electrically isolate adjacent conductive plates;
a means for driving electrical stimulus to each additional conductive plate electrically connected to each said additional conductive plate;
a means for measuring the presence of capacitive interaction between said conductive plates electrically connected to said conductive plates; and
a means for detecting whether capacitive interactions between said conductive plates is destroyed electrically connected to said conductive plates.

5. The capacitive page opening detector in accordance with claim 1, wherein the means for detecting whether capacitive interactions between said conductive plates is destroyed is capable of detecting the destruction of capacitive interactions when said conductive plates are substantially separated.

6. The capacitive page opening detector in claim 2 further comprising a means of identifying the adjacent capacitive plates at which the capacitive interaction is destroyed.

7. The capacitive page opening detector in claim 2 further comprising a means of detecting the destruction of capacitive interactions when any two adjacent said conductive plates are substantially separated.

8. The capacitive page opening detector in claim 3 further comprising a means of identifying the adjacent capacitive plates at which the capacitive interaction is destroyed.

9. The capacitive page opening detector in claim 3 further comprising a means of detecting the destruction of capacitive interactions when any two adjacent said conductive plates are substantially separated.

10. The capacitive page opening detector in claim 4 further comprising a means of identifying the adjacent capacitive plates at which the capacitive interaction is destroyed.

11. The capacitive page opening detector in claim 4 further comprising a means of detecting the destruction of capacitive interactions when any two adjacent said conductive plates are substantially separated.

10. The capacitive page opening detector in claim 1, further comprising a means of signaling a response to changes in detected capacitive interactions between conductive plates electrically connected to said means for detecting whether capacitive interactions between said conductive plates is destroyed.

11. The capacitive page opening detector in claim 2, further comprising a means of signaling a response to changes in detected capacitive interactions between conductive plates electrically connected to said means for detecting whether capacitive interactions between said conductive plates is destroyed.

12. The capacitive page opening detector in claim 3, further comprising a means of signaling a response to changes in detected capacitive interactions between conductive plates electrically connected to said means for detecting whether capacitive interactions between said conductive plates is destroyed.

13. The capacitive page opening detector in claim 4, further comprising a means of signaling a response to changes in detected capacitive interactions between conductive plates electrically connected to said means for detecting whether capacitive interactions between said conductive plates is destroyed.
